(19) United States
(12) Patent Application Publication
(10) Pub. No.: US 2015/0243695 A1
(43) Pub. Date: Aug. 27, 2015

(54) IMAGING SYSTEMS WITH ACTIVATION MECHANISMS

(71) Applicant: Semiconductor Components Industries, LLC, Phoenix, AZ (US)

(72) Inventors: Ulrich Boettiger, Garden City, ID (US); Swarnal Borthakur, Boise, ID (US)

(21) Appl. No.: 14/191,891

(22) Filed: Feb. 27, 2014

(51) Int. Cl. H01L 27/146; G01N 21/75

(52) U.S. Cl. CPC H01L 27/14621; G01N 21/75; G01N 2201/12

(57) ABSTRACT

An imaging system may be used to image a fluid sample containing particles. The imaging system may include a fluid channel that receives the fluid sample and a reactive agent that selectively attaches to target particles in the fluid sample. An activation mechanism may be operated to trigger a chemical reaction between the fluid sample and the reactive agent. The imaging system may include an image sensor integrated circuit and image sensor pixels to capture a detectable effect of the chemical reaction. The image sensor integrated circuit may be synchronized to the activation mechanism such that it captures an image of the fluid sample after the chemical reaction is triggered by the activation mechanism.

### BACKGROUND

This relates generally to imaging systems, and more particularly, to using such systems to image and evaluate samples containing chemical samples.

Such imaging systems may include near-field sensor systems such as opto-fluidic systems. Opto-fluidic sensors can image fluid samples such as various chemical and biological substances. The samples are flowed over a set of image sensor pixels in a channel. The image sensor pixels may be associated with an image sensor pixel array. As the sample flows through the channel, image data from the pixels may be acquired and processed to form images of the sample.

Agents that selectively attach to certain particles in the sample may be introduced in the channel to acquire images that identify target particles of the sample that react with the agents. However, a common challenge with such methods is the immediate and inhomogenous onset and drawn-out progression of the chemical reactions once the agent binds to the particle, which may result in undesirable signal-to-noise ratios.

It would therefore be desirable to provide improved imaging systems for chemically reactive samples.

### BRIEF DESCRIPTION OF THE DRAWINGS

FIG. 1 is a diagram of an illustrative imaging system that may include an image sensor in accordance with an embodiment of the present invention.

FIG. 2 is a diagram of an illustrative system for imaging and evaluating samples in accordance with an embodiment of the present invention.

FIG. 3 is a diagram of illustrative steps involved in imaging samples in accordance with an embodiment of the present invention.

FIG. 4 is a flow chart of illustrative steps involved in imaging samples in accordance with an embodiment of the present invention.

FIG. 5 is a block diagram of an imaging system employing the embodiment of FIG. 2 in accordance with an embodiment of the present invention.

### DETAILED DESCRIPTION

Electronic devices such as digital cameras, computers, cellular telephones, and other electronic devices include image sensors that gather incoming image light to capture an image. The image sensors may include arrays of imaging pixels. The pixels in the image sensors may include photosensitive elements such as photodiodes that convert the incoming image light into image signals. Image sensors may have any number of pixels (e.g., hundreds or thousands or more). A typical image sensor may, for example, have hundreds of thousands or millions of pixels (e.g., megapixels). Image sensors may include control circuitry such as circuitry for operating the imaging pixels and readout circuitry for reading out image signals corresponding to the electric charge generated by the photosensitive elements.

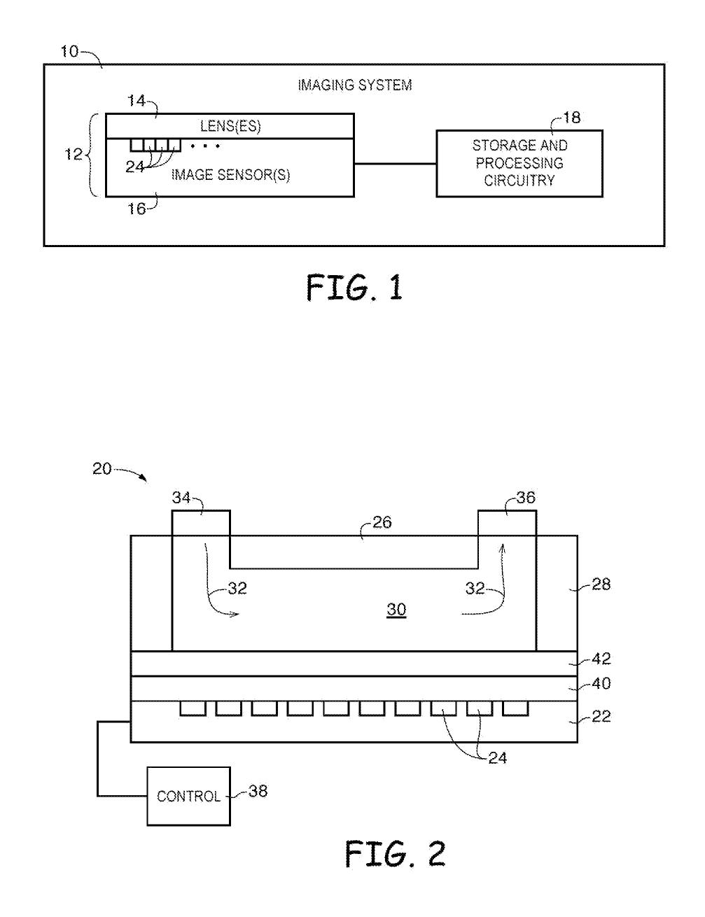

FIG. 1 is a diagram of an illustrative electronic device that uses an image sensor to capture images. Electronic device 10 of FIG. 1 may be a portable electronic device such as a camera, a cellular telephone, a video camera, or other imaging device that captures digital image data. Camera module 12 may be used to convert incoming light into digital image data. Camera module 12 may include one or more lenses 14 and one or more corresponding image sensors 16. During image capture operations, light from a scene may be focused onto image sensor 16 by lens 14. Image sensor 16 provides corresponding digital image data to processing circuitry 18. Image sensor 16 may, for example, be a backside illumination image sensor. If desired, camera module 12 may be provided with an array of lenses 14 and an array of corresponding image sensors 16. Image sensor 16 may include an array of image sensor pixels such as an array of image sensor pixels 24 and a corresponding array of optional color filter elements.

Processing circuitry 18 may include one or more integrated circuits (e.g., image processing circuits, microprocessors, storage devices such as random-access memory and non-volatile memory, etc.) and may be implemented using components that are separate from camera module 12 and/or that form part of camera module 12 (e.g., circuits that form part of an integrated circuit that includes image sensors 16 or an integrated circuit within module 12 that is associated with image sensors 16). Image data that has been captured by camera module 12 may be processed and stored using processing circuitry 18. Processed image data may, if desired, be provided to external equipment (e.g., a computer or other device) using wired and/or wireless communications paths coupled to processing circuitry 18.

Electronic device 10 may include opto-fluidic sensor system 20. Sensor system 20 may include an image sensor integrated circuit such as image sensor integrated circuit 22. Image sensor integrated circuit 22 may be formed from a semiconductor substrate material such as silicon and may contain numerous image sensor pixels 24. Complementary metal-oxide-semiconductor (CMOS) technology or other image sensor integrated circuit technologies may be used in forming integrated circuit 22 and image sensor pixels 24.

Image sensor pixels 24 may form part of an array of image sensor pixels on image sensor integrated circuit 22 (e.g. a rectangular array). Some of the pixels may be actively used for gathering light. Other pixels may be inactive or may be omitted from the array during fabrication. In arrays in which fabricated pixels are to remain inactive, the inactive pixels may be covered with metal or other opaque materials, may be depowered, or may otherwise be inactivated. There may be any suitable number of pixels fabricated in integrated circuit 22 (e.g., tens, hundreds, thousands, millions, etc.). The number of active pixels in integrated circuit 22 may be tens, hundreds, thousands, or more).

Image sensor integrated circuit 22 may be covered with a transparent layer of material such as glass layer 26 or other covering layers. Layer 26 (sometimes referred to as cover glass 26) may, if desired, be colored or covered with filter coatings (e.g., coatings of one or more different colors to filter light). Structures such as bond layer 28 (e.g., polymer standoffs) may be used to elevate the lower surface of glass layer 26 from the upper surface of image sensor integrated circuit 34, forming a channel such as channel 30. During operation, a fluid sample may flow through channel 30 as illustrated by arrows 32. A fluid source such as fluid source 34 may be used to introduce the sample into channel 30. The sample may, for example, be dispensed from a pipette, from a drop, from a fluid-filled reservoir, or from tubing coupled to an external pump. The fluid sample may exit channel 30 and be collected in reservoir 36. Control circuitry 38 (which may be implemented as external circuitry or as circuitry that is embedded within image sensor integrated circuit 22) may be used to process the image data that is acquired using sensor pixels 24.

Sensor system 20 may include an optional color filter layer such as color filter layer 40. Color filter layer 40 may be formed over image sensor integrated circuit 22. The color filter layer 40 may include individual color filter elements associated with each image pixel 24. Color filter layer 40 may include red color filter elements (e.g. photoresistive material that passes red light and blocks other colors of light from passing), blue color filter elements, green color filter elements, infrared color filter elements, or other color filter elements. Sensor system 20 may also include optional protective layers such as protective layers 42 to prevent damage to sensor system 20 from fluids used in sample preparations that may be flowed through channel 30. Protective layers 42 may be formed from materials such as base-resistant materials, acid-resistant materials, or other protective materials and may be formed from one or multiple layers of materials. Protective layers 42 may also be formed along other areas of the channel in addition to the bottom surface of the channel.

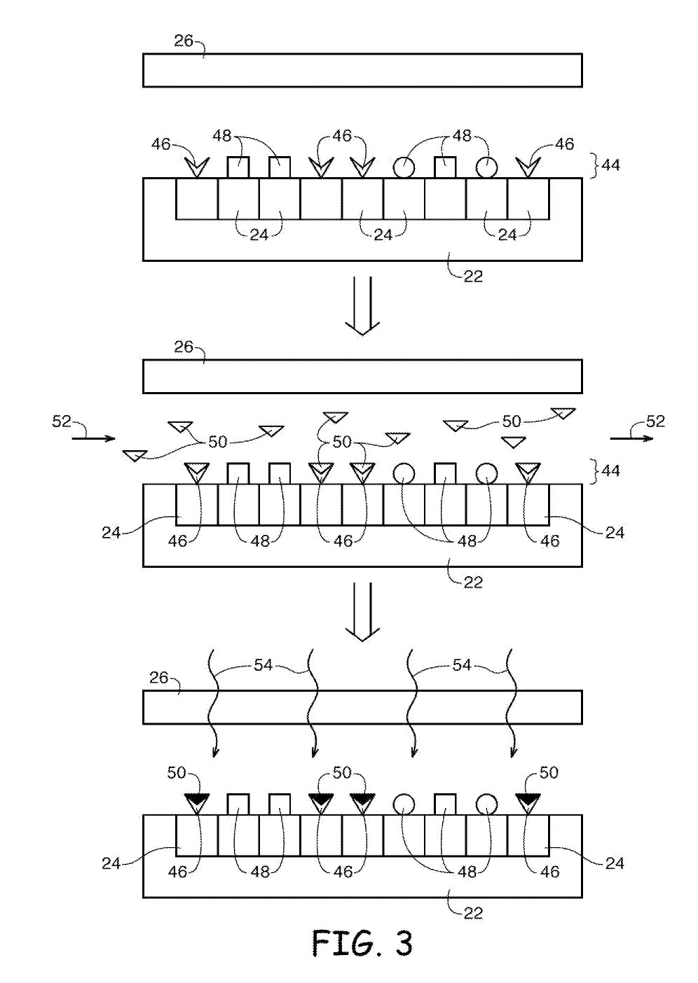

In FIG. 3, a simplified diagram of steps involved in imaging samples using a sensor system such as sensor system 20 is shown. A sample to be imaged such as sample 44 may be flowed through a channel of the sensor system such as channel 16 in FIG. 2. Sample 22 may be captured using a global shutter method. In a global shutter capture, each image captured is an image of a single point in time based on image data from the entire array of pixels 24. The sample may chemisorbed or physisorbed to a surface above the array of pixels 24 in image sensor integrated circuit 22. Sample 44 may be cells, proteins, ribonucleic acid (RNA), deoxyribonucleic acid (DNA), reagents, fluorescent species, or other biological or chemical agents or particles. Sample 44 may contain a number of different types of particles; for example, sample 44 may be a DNA sample containing a number of different DNA molecules, and analyzing the DNA sample may require identifying a particular type of DNA molecule. Sample 44 may include target particles such as target particles 46 (illustrated as “V-shaped” particles in FIG. 3) and non-target particles such as non-target particles 48 (illustrated as square-shaped and circle-shaped particles in FIG. 3).

A reactive agent such as reactive agent 50 may be introduced into channel 16 and flowed over sample 44 as illustrated by arrows 52. Reactive agent 50 may have chemical properties that cause it to selectively attach to target particles 46. For example, reactive agent 50 may be enzyme molecules with a shape that is specifically compatible for binding to target particles 46. This is merely exemplary; reactive agent 50 can be any selectively targeted agent for interacting with target particles in sample 44. Reactive agent 50 and target particles 46 may require an additional activation step after attaching to each other to chemically react with each other.

After reactive agent 50 has been flowed over sample 44 to selectively bind to target particles 46, an activation mechanism (also known as a trigger signal) such as activation mechanism 54 may be applied to sample 44. Activation mechanism 54 may activate (i.e. trigger) the chemical reaction between reactive agent 50 and target particles 46. The chemical reaction may result in a detectable effect that may be captured by image pixels 24; for example, an activated chemical reaction between reactive agent 50 and target particles 46 may result in photons or protons emitted (depicted as darkened reactive agents 50 in FIG. 3), which may be detected and localized by the array of image pixels 24 and integrated circuit 22. The activation mechanism may include a light pulse that is applied to sample 22 through glass layer 26 and triggers a reaction between reactive agent 50 and target particles 46. Activation mechanism 54 may also be non-optical or non-detectable by pixels 24 and may eliminate the requirement for optional color filter 40 in image sensor system 20; for example, activation mechanism may include a heat pulse, a pressure pulse (e.g. an ultrasonic pulse), an electric field, or a magnetic field to sample 44.

Samples 22 may also be flowed through channel 30 such that image data may be acquired as samples 22 pass by pixels 24. In effect, the cells are “scanned” across the pattern of pixels 24 in channel 30 in much the same way that a printed image is scanned in a fax machine. In addition to static capture of sample 22, activation mechanism 54 may enable a rolling shutter capture of sample 22. In other words, the chemical reaction between sample 22 and reactive agent 50 may be repeatedly activated by an activation mechanism 54 at predetermined time intervals while the image sensor captures the detectable effect of the chemical reaction at times corresponding to the predetermined time intervals. For example, a light pulse may be applied to sample 22 and reactive agent 50 to trigger a chemical reaction between sample 22 and reactive agent 50 that results in photon emissions of a particular frequency. The light pulse may be applied to sample 22 at regular intervals and image sensor integrated circuit 22 may be synchronized with the operation of the light pulse such that image pixels 24 capture an image of sample 22 that shows the photon emissions. This is merely exemplary; activation mechanism 54 may be any suitable mechanism for triggering a chemical reaction between sample 22 and reactive agent 50. As another example, the trigger reaction between sample 22 and reactive agent 50 may result in various effects such as a proton release. The image sensor integrated circuit 22 may be operated and capture sample 22 continuously and independent of the operation of activation mechanism, or control circuitry 38 may coordinate the timing of application of activation mechanism 54 to sample 22. In other words, control circuitry 38 may synchronize the image capture operation of image sensor integrated circuit 22 with the application of activation mechanism 54. Controlled synchronization of activation mechanism 54 and reactive agent may be applied in both rolling shutter and global shutter type operations of the image sensor integrated circuit 22.

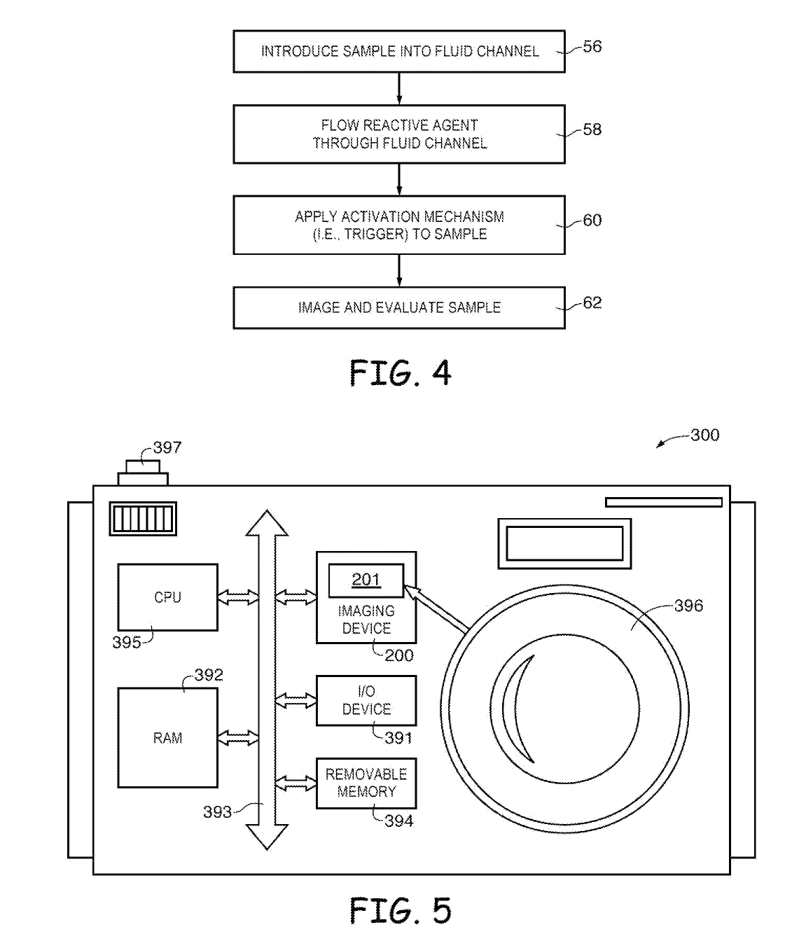

FIG. 4 is a flowchart of the illustrative steps depicted in FIG. 3. At step 56, a sample such as sample 44 may be introduced into a fluid channel such as channel 16. Sample 44 may be flowed through a channel of the sensor system such as channel 16 in FIG. 2. Sample 44 may chemisorbed or physisorbed to a surface above the array of pixels 24 in image sensor integrated circuit 22, or sample 44 may flow through channel 30 such that image data may be acquired as samples 22 pass by pixels 24. Sample 44 may be cells, proteins, RNA, DNA, reagents, fluorescent species, or other biological or chemical agents or particles. Sample 44 may be a DNA sample containing a number of different DNA molecules, and analyzing the DNA sample may require identifying a particular type of DNA molecule. Sample 44 may include target particles such as target particles 46 (illustrated as “V-shaped” particles in FIG. 3) and non-target particles such as non-target particles 48 (illustrated as square-shaped and circle-shaped particles in FIG. 3).

At step 58, a reactive agent such as reactive agent 50 may be flowed through the fluid channel containing sample 44. Reactive agent 50 may have chemical properties that cause it to selectively interact with target particles 46. For example, reactive agent 50 may be enzyme molecules with a shape that is specifically compatible for binding to target particles 46. This is merely exemplary; reactive agent 50 can be any selectively targeted agent for interacting with target particles in sample 44. Reactive agent 50 and target particles 46 may require an additional activation step after attaching to each other to chemically react with each other.

At step 60, an activation mechanism (i.e. trigger) may be applied to the sample to activate or trigger the reactions between reactive agent 50 and sample 44. Activation mechanism 54 may activate (i.e. trigger) the chemical reaction between reactive agent 50 and target particles 46. The activation mechanism may include applying a light pulse, a heat pulse, or a pressure pulse (e.g. an ultrasonic pulse) to sample 44. Activation mechanism 54 may be an electric or magnetic field that triggers a reaction between reactive agent 50 and target particles 46.

At step 62, the sample may be imaged and evaluated based on effects that result from the activated reaction between reactive agent 50 and sample 44. For example, the activated chemical reaction may result in a detectable effect that may be captured by image pixels 24; for example, an activated chemical reaction between reactive agent 50 and target particles 46 may result in photons or protons emitted, which is detected and localized by the array of image pixels. In addition to static capture of sample 22, activation mechanism 54 may enable a rolling shutter capture of sample 22. In other words, the chemical reaction between sample 22 and reactive agent 50 may be repeatedly activated by an activation mechanism 54 at predetermined time intervals while the image sensor captures the detectable effect of the chemical reaction at times corresponding to the predetermined time intervals. Control circuitry 38 may coordinate the timing of application of activation mechanism 54 to sample 22 and may synchronize the image capture operation of image sensor integrated circuit 22 with the application of activation mechanism 54.

FIG. 5 shows in simplified form a typical processor system 300, such as a digital camera, which includes an imaging device 200. Imaging device 200 may include an imaging system such as image sensor system 20 of FIG. 2 having an array 201 of image pixels 24. Processor system 300 is exemplary of a system having digital circuits that may include imaging device 200. Without being limiting, such a system may include a computer system, still or video camera system, scanner, machine vision, vehicle navigation, video phone, surveillance system, auto focus system, star tracker system, motion detection system, image stabilization system, and other systems employing an imaging device.

Processor system 300, which may be a digital still or video camera system, may include a lens such as lens 396 for focusing an image onto a pixel array such as pixel array 201 when shutter release button 397 is pressed. Processor system 300 may include a central processing unit such as central processing unit (CPU) 395. CPU 395 may be a microprocessor that controls camera functions and one or more image flow functions and communicates with one or more input/output (I/O) devices 391 over a bus such as bus 393. Imaging device 200 may also communicate with CPU 395 over bus 393. System 300 may include random access memory (RAM) 392 and removable memory 394. Removable memory 394 may include flash memory that communicates with CPU 395 over bus 393. Imaging device 200 may be combined with CPU 395, with or without memory storage, on a single integrated circuit or on a different chip. Although bus 393 is illustrated as a single bus, it may be one or more buses or bridges or other communication paths used to interconnect the system components.

Various embodiments have been described illustrating an apparatus for imaging and evaluating fluid samples with activation mechanisms. An imaging system may include an image sensor integrated circuit containing image sensor pixels, a fluid channel over the image sensor integrated circuit that receives fluid sample and a reactive agent that selectively attaches to target particles in the fluid sample, and an activation mechanism that activates and/or triggers a chemical reaction between the target particles and the reactive agent. The image sensor integrated circuit performs an image capture operation of the sample and an effect of the chemical reaction using the image sensor pixels. The imaging system includes control circuitry that operates the image sensor integrated circuit and the activation mechanism. The activation mechanism may include a light pulse, a heat pulse, a pressure pulse, an electric field, or a magnetic field.

The image sensor integrated circuit may capture an image indicating photons produced by the chemical reaction. The control circuitry may synchronize the image capture operation of the image sensor integrated circuit with the operation of the activation mechanism such that the image capture operation occurs after the operation of the activation mechanism. The activation mechanism may enable a global or a rolling shutter capture of the sample. The control circuitry may operate the activation mechanism and/or the image sensor integrated circuit at predetermined regular time intervals. The control circuitry may also operate the image capture operation of the image sensor integrated circuit continuously and/or operate the image capture operation of the image sensor integrated circuit independent from the operation of the activation mechanism. The reactive agent may be an enzyme molecule. The imaging system may also include a central processing unit, a memory, and input-output circuitry.

What is claimed is:

1. An apparatus, comprising:
an image sensor integrated circuit containing image sensor pixels;
a fluid channel over the image sensor integrated circuit, wherein the fluid channel is configured to receive a fluid sample and a reactive agent that selectively attaches to target particles in the fluid sample;
an activation mechanism configured to activate a chemical reaction between the target particles and the reactive agent, wherein the image sensor integrated circuit is configured to perform an image capture operation of an effect of the chemical reaction using the image sensor pixels; and
control circuitry to operate the image sensor integrated circuit and the activation mechanism.

2. The apparatus defined in claim 1, wherein the activation mechanism comprises a light pulse.

3. The apparatus defined in claim 1, wherein the activation mechanism comprises an activation mechanism selected from the group consisting of: a heat pulse, a pressure pulse, an electric field, and a magnetic field.

4. The apparatus defined in claim 1, wherein the image sensor integrated circuit is configured to capture an image indicating photons produced by the chemical reaction.

5. The apparatus defined in claim 1, wherein the control circuitry is configured to synchronize the image capture operation of the image sensor integrated circuit with the operation of the activation mechanism such that the image capture operation occurs after the operation of the activation mechanism.

6. The apparatus defined in claim 1, wherein the control circuitry is configured to operate the activation mechanism at predetermined regular time intervals.

7. The apparatus defined in claim 1, wherein the control circuitry is configured to operate the image capture operation of the image sensor integrated circuit continuously.

8. The apparatus defined in claim 1, wherein the control circuitry is configured to operate the image capture operation of the image sensor integrated circuit independent from the operation of the activation mechanism.

9. The apparatus defined in claim 1, wherein the control circuitry is configured to operate the image capture operation of the image sensor integrated circuit at predetermined regular time intervals.

10. The apparatus defined in claim 1, wherein the reactive agent comprises an enzyme molecule.

11. A method for imaging a sample with an imaging system having a channel, comprising:
flowing a sample through the channel, wherein the sample includes target particles;
flowing a reactive agent through the channel, wherein the reactive agent binds selectively to the target particles in the sample;
triggering a chemical reaction between the reactive agent and the target particles; and
capturing an image of the sample.

12. The method defined in claim 11 wherein triggering the chemical reaction between the reactive agent and the target particles comprises operating an activation mechanism in the imaging system.

13. The method defined in claim 12, wherein operating the activation mechanism comprises applying a light pulse to the reactive agent and the target particles.

14. The method defined in claim 12, wherein operating the activation mechanism comprises applying a heat pulse to the reactive agent and the target particles.

15. The method defined in claim 11, wherein capturing the image of the sample comprises capturing the image continuously.

16. The method defined in claim 11, wherein capturing an image of the sample comprises capturing the image after triggering the chemical reaction.

17. The method defined in claim 11, wherein capturing an image of the sample comprises capturing the image at predetermined regular time intervals.

18. A system, comprising:
a central processing unit;
memory;
input-output circuitry; and
an imaging sensor integrated circuit having a pixel array;
a channel over the pixel array that is configured to receive a sample containing target particles and reactive agents that selectively attach to the target particles; and
an activation mechanism that is configured to trigger a chemical reaction between the target particles and the reactive agents.

19. The system defined in claim 18 wherein the activation mechanism enables a rolling shutter capture of the sample.

20. The system defined in claim 18 wherein the activation mechanism comprises a heat pulse.

21. The system defined in claim 18 wherein the activation mechanism enables a global shutter capture of the sample.
